(19) United States
(12) Patent Application Publication
(10) Pub. No.: US 2026/0358685 A1
(43) Pub. Date: Nov. 12, 2026

(54) IMAGE PICKUP APPARATUS CAPABLE OF IMPROVING GRIP CAPABILITY OF THE IMAGE PICKUP APPARATUS WHILE SUPPRESSING TEMPERATURE RISE INSIDE THE IMAGE PICKUP APPARATUS

(71) Applicant: CANON KABUSHIKI KAISHA, Tokyo (JP)

(72) Inventor: HAYATO MANO, Tokyo (JP)

(21) Appl. No.: 19/660,543

(22) Filed: Apr. 28, 2026

(30) Foreign Application Priority Data
May 12, 2025 (JP) 2025-079784

(51) Int. Cl. G03B 17/55; G03B 17/12; G03B 17/56; H04N 23/52; H05K 7/20

(52) U.S. Cl. CPC G03B 17/55; G03B 17/12; G03B 17/563; G03B 17/566; H04N 23/52; H05K 7/20145; H05K 7/20154

(57) ABSTRACT

An image pickup apparatus includes a lens barrel, a gripping portion for gripping a case, a first circuit board, on which a first heat generating element is mounted, disposed on a first face, a second circuit board, on which a second heat generating element is mounted, disposed on a second face substantially perpendicular to the first face, and a heat dissipation device disposed on a third face and having a flow path connecting an intake port to an exhaust port. The third face is a face that is different from a face, on which the gripping portion is located, and that is substantially perpendicular to and adjacent to the first face and the second face. The heat dissipation device is thermally connected to the first heat generating element by a first heat transfer member, and is thermally connected to the second heat generating element by a second heat transfer member.

### BACKGROUND

### Field of the Technology

The present disclosure relates to an image pickup apparatus.

### Description of The Related Art

In an image pickup apparatus, there is a need for a structure with a higher heat dissipation effect (a higher heat dissipation capacity) to cope with the increased heat generation resulting from the increased power consumption caused by the recent increase in the pixel count of an image pickup device (an image sensor), etc. For example, a structure has been proposed in which the inside of an image pickup apparatus is cooled by using a blower fan and a duct (see Japanese Patent No. 6882093).

However, with the structure disclosed in Japanese Patent No. 6882093, since the blower fan and the duct are provided to cool the inside of the image pickup apparatus, the weight of the image pickup apparatus increases, and the image pickup apparatus also becomes larger. In addition, since the blower fan and the duct are disposed on a side portion of a lens barrel between the lens barrel and a gripping portion, a distance between the gripping portion and the lens barrel that is a heavy object increases when a user grips the image pickup apparatus. There has been an issue that as the centroid of the image pickup apparatus and the gripping position become separated, the load on the user's hand increases, and the grip capability decreases.

### SUMMARY

The present disclosure provides an image pickup apparatus capable of improving the grip capability of the image pickup apparatus while suppressing a temperature rise inside the image pickup apparatus.

Accordingly, an aspect of the present disclosure provides an image pickup apparatus comprising a lens barrel, a gripping portion for gripping a case of the image pickup apparatus, a first circuit board, on which a first heat generating element is mounted, the first circuit board being disposed on a first face of the lens barrel, a second circuit board, on which a second heat generating element is mounted, the second circuit board being disposed on a second face of the lens barrel that is substantially perpendicular to the first face, and a heat dissipation device configured to be disposed on a third face of the lens barrel and have a flow path connecting an intake port provided in the case to an exhaust port provided in the case. The third face is a face that is different from a face, on which the gripping portion is located, and that is substantially perpendicular to the first face and the second face and is adjacent to the first face and the second face. The heat dissipation device is thermally connected to the first heat generating element by a first heat transfer member, and is thermally connected to the second heat generating element by a second heat transfer member.

Features of the present disclosure will become apparent from the following description of embodiments with reference to the attached drawings. The following description of embodiments is described by way of example.

### BRIEF DESCRIPTION OF THE DRAWINGS

FIGS. 1A and 1B are a front perspective view and a rear perspective view of an image pickup apparatus according to one embodiment of the present disclosure.

FIGS. 2A and 2B are a front perspective view and a rear perspective view, respectively, illustrating a state where a user is gripping the image pickup apparatus.

FIGS. 3A, 3B, and 3C are a front perspective view, a rear perspective view, and a sectional view taken along line A-A of a heat dissipation device.

FIGS. 4A and 4B are perspective views of an image pickup unit.

FIGS. 5A and 5B are a perspective view and an exploded perspective view, respectively, illustrating an internal structure of the image pickup apparatus.

FIGS. 6A and 6B are a top view and a sectional view taken along line B-B of the image pickup apparatus.

FIG. 7 is an enlarged view of an area E shown in FIG. 6B.

### DESCRIPTION OF THE EMBODIMENTS

The present disclosure will now be described in detail below with reference to the accompanying drawings showing embodiments thereof.

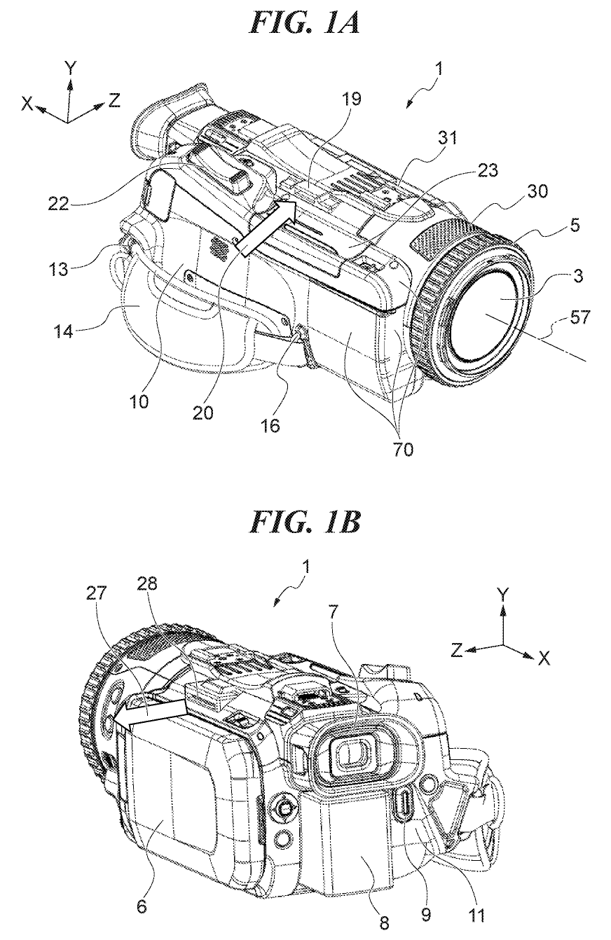

FIGS. 1A and 1B are a front perspective view and a rear perspective view, respectively, of an image pickup apparatus 1 according to one embodiment of the present disclosure. The image pickup apparatus 1 is, for example, a video camera.

Hereafter, the direction of each part will be referred to, based on X, Y, and Z coordinate axes that are shown in FIGS. 1A, 1B, etc. For convenience, in the present disclosure, in a direction parallel to a photographing optical axis 57, a subject side is defined as the front, and a photographer side (a user side) is defined as the rear. The X-axis direction is parallel to the optical axis direction shown in FIG. 1A, and the subject side is defined as the -X side. In a direction perpendicular to the X-axis, the width direction of the image pickup apparatus 1 is defined as the Z-axis direction, and the right side as viewed from the subject side is defined as the +Z side. In addition, the top-and-bottom direction of the image pickup apparatus 1 is defined as the Y-axis direction, and the upper side is defined as the +Y side.

A lens unit 3 is disposed at a front portion of the image pickup apparatus 1, and an operating ring 5, which allows for manual focus and other operations, is provided on an outer circumference portion of the lens unit 3. A display unit 6, which is configured by a liquid crystal display (an LCD) or the like, is provided on the +Z side in the image pickup apparatus 1, so that the display unit 6 is capable of being opened and closed. A viewfinder 7, a battery 8, a recording button 9 are disposed at a rear portion of the image pickup apparatus 1.

A first grip portion 10 (a gripping portion) for a user to grip a case 70 of the image pickup apparatus 1 is provided on the -Z side in the image pickup apparatus 1. A second grip portion 11 is provided below the recording button 9 disposed at the rear portion of the image pickup apparatus 1. A first grip belt holder 13 is provided on the +X side of the first grip portion 10, and a second grip belt holder 16 is provided on the -X side of the first grip portion 10. A grip belt 14, which is fixed to the first grip belt holder 13 and the second grip belt holder 16, is a belt member for the user to grip the image pickup apparatus 1. The first grip portion 10 is disposed between the first grip belt holder 13 and the second grip belt holder 16 in the optical axis direction.

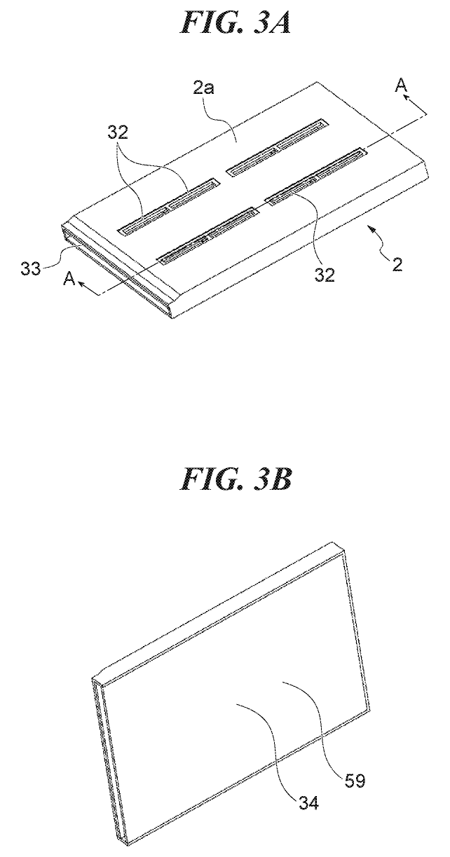

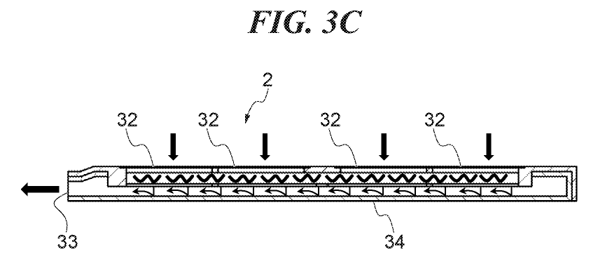

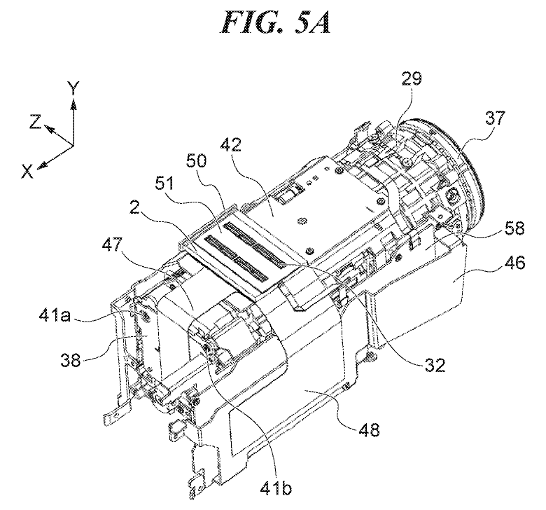

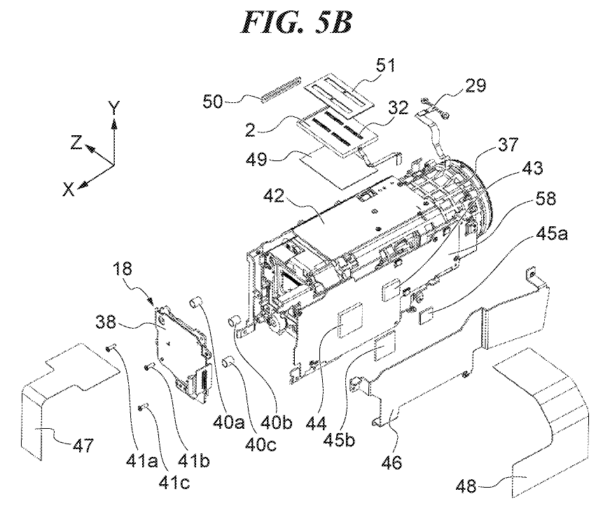

A top portion of the image pickup apparatus 1 is equipped with a rocker zoom 22 and an openable/closable card lid 23. A recording medium (not shown) such as an SD card is inserted inside the card lid 23. In addition, starting from the subject side, a microphone hole 30, which communicates with a microphone 29 (see FIGS. 5A and 5B), and an accessory fixing portion 31, which is a mounting portion to which an external accessory is capable of being attached, are disposed in order. The image pickup apparatus 1 is equipped with a heat dissipation device 2 (see FIG. 3A), which will be described below. The heat dissipation device 2 is a device that takes in ambient air, and exhausts it to the outside along with the heat generated inside the image pickup apparatus 1.

An intake port 19, which opens in the -Z direction, is disposed at the top portion of the image pickup apparatus 1 on the -Z side. An exhaust port 28, which opens in the +Z direction, is disposed at the top portion of the image pickup apparatus 1 on the +Z side. The intake port 19 and the exhaust port 28 are formed in the case 70 of the image pickup apparatus 1. An arrow 20 shown in FIG. 1A indicates an intake airflow to the intake port 19, and an arrow 21 shown in FIG. 1B indicates an exhaust airflow from the exhaust port 28.

It should be noted that since the grip belt 14 and the battery 8 are capable of being attached (mounted) later, the grip belt 14 and the battery 8 may not be included in the components of the image pickup apparatus 1.

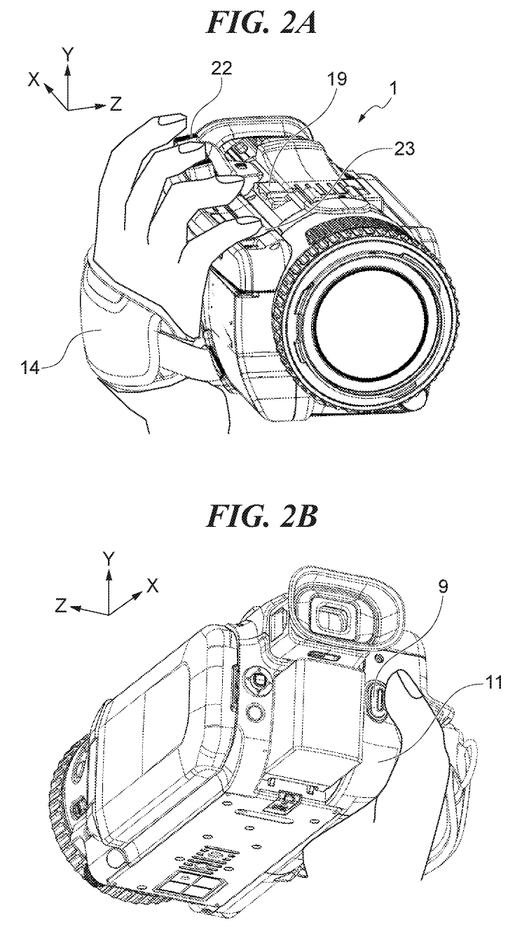

FIGS. 2A and 2B are a front perspective view and a rear perspective view, respectively, illustrating a state where the user is gripping the image pickup apparatus 1.

As shown in FIGS. 2A and 2B, the user places the little finger, the ring finger, the middle finger, and the index finger of his/her right hand between the grip belt 14 and the first grip portion 10 (see FIG. 1A), places his/her right palm against the first grip portion 10, and places the back of his/her right hand against the grip belt 14. The user, if necessary, places the little finger and the ring finger on the card lid 23 and rests the base of his/her thumb against the second grip portion 11. In this state, the user operates the rocker zoom 22 with the index finger and the middle finger, and operates the recording button 9 with his/her thumb.

FIGS. 3A and 3B are a front perspective view and a rear perspective view, respectively, of the heat dissipation device 2. FIG. 3C is a sectional view taken along line A-A shown in FIG. 3A.

The heat dissipation device 2 includes a back face 59 (an opposing face) and a main face 2a opposite to the back face 59. The back face 59 is a face facing a top face of a lens barrel 37 in the Y-axis direction, and is parallel to the main face 2a.

The main face 2a is provided with a plurality of air intake ports 32 for drawing in outside air. The heat dissipation device 2 is equipped with an air exhaust port 33. The air exhaust port 33 opens in a direction substantially perpendicular to the back face 59 and the main face 2a. The back face 59 is configured by a heat diffusion plate 34 (a heat diffusion portion) that is made of a member (a material) with high thermal conductivity, such as copper or aluminum. The heat dissipation device 2 has a flow path that connects the intake port 19 to the exhaust port 28 (see FIGS. 1A and 1B). The heat diffusion plate 34 constitutes a part of the flow path, which is from the air intake ports 32 to the air exhaust port 33.

Arrows shown in FIG. 3C indicate the flow of the air, and wavy lines shown in FIG. 3C indicate a thin film enclosed within the heat dissipation device 2. This thin film vibrates at high speed, causing the heat dissipation device 2 to draw in the air from the air intake ports 32. The air drawn in absorbs heat from the heat diffusion plate 34, and then is discharged from the air exhaust port 33 of the heat dissipation device 2. In this way, the heat dissipation device 2 is capable of cooling heat dissipation target component(s).

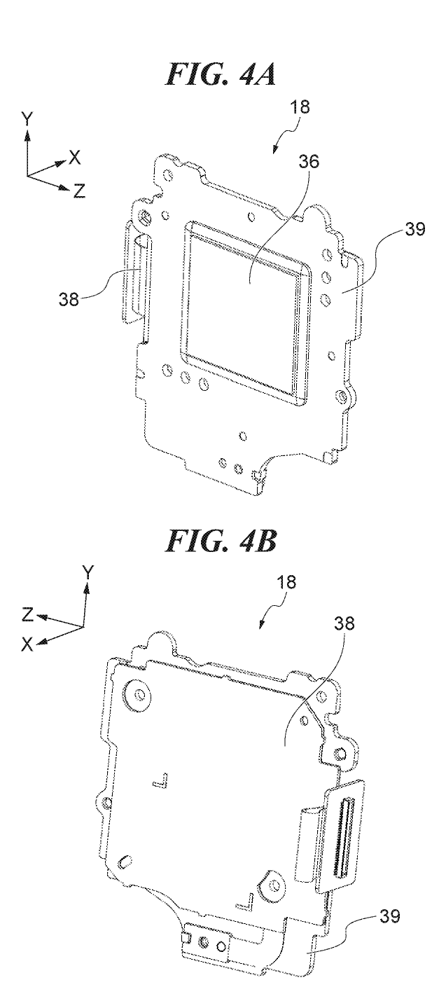

Next, the heat dissipation structure of the image pickup apparatus 1 will be described with reference to FIGS. 4A - 6B.

FIGS. 4A and 4B are perspective views of an image pickup unit 18, respectively. An image pickup device (an image sensor) 36 is an element that converts the image that has entered through the lens barrel 37 (see FIG. 5A) into electrical signals. The image pickup device 36 generates heat when processing the electrical signals. When the image pickup device 36 is at a high temperature (becomes hot), noise increases, image quality deteriorates, and its lifespan is shortened. Therefore, the image pickup device 36 is cooled by a method that will be described below. The image pickup device (the image sensor) 36 is mounted on a sensor circuit board 38 (a second circuit board), and the image pickup device (the image sensor) 36 and the sensor circuit board 38 are bonded and fixed to a sensor plate 39 with UV-curing resin or the like. The image pickup unit 18 is disposed on a back face of the lens barrel 37.

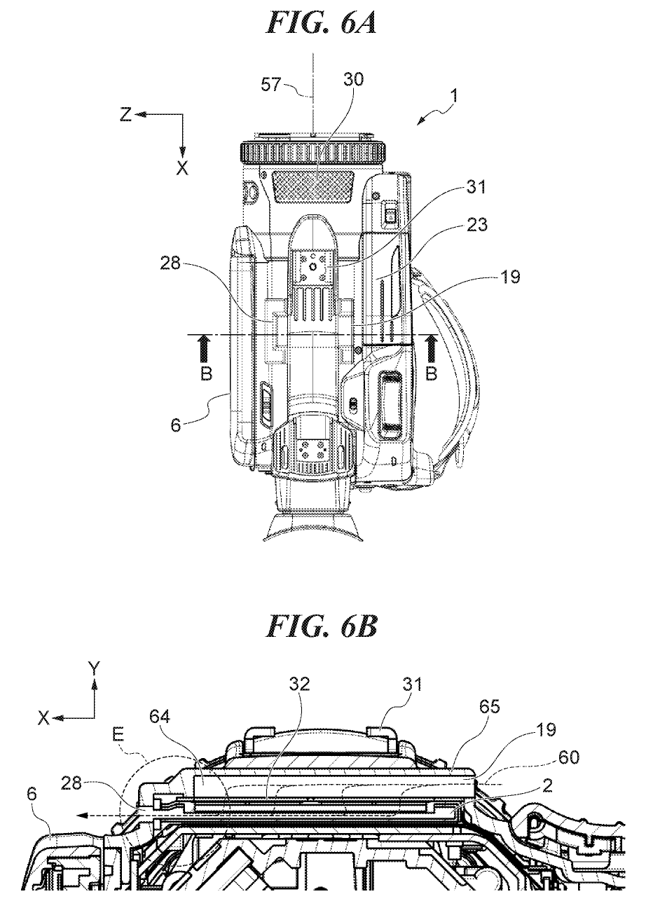

FIGS. 5A and 5B are a perspective view and an exploded perspective view, respectively, of an internal structure of the image pickup apparatus 1, illustrating the heat dissipation structure of the image pickup apparatus 1. FIGS. 6A and 6B are a top view and a sectional view taken along line B-B, respectively, of the image pickup apparatus 1.

As shown in FIG. 5B, the image pickup unit 18 is fixed to the lens barrel 37 by screws 41 (a screw 41a, a screw 41b, a screw 41c, and a screw 41d) so as to counteract the reaction force of coil springs 40 (a coil spring 40a, a coil spring 40b, a coil spring 40c, and a coil spring 40d) located on the back face of the lens barrel 37. By changing the tightening amount of each screw 41, the tilt of the image pickup device 36 with respect to the optical axis 57 is capable of being adjusted.

One end portion of a thin and flexible graphite sheet 47 made of carbon is attached to a back face (the +X side face) of the sensor circuit board 38. The other end portion of the graphite sheet 47 is attached to a holder member 42 (see FIG. 5A) of the lens barrel 37.

A first IC chip 43 shown in FIG. 5B is responsible for performing predetermined image processing with respect to captured image data (photographed image data) from the image pickup device 36 and outputting it as a video image. Specifically, the first IC chip 43 performs image compression, noise reduction, color correction, and frame rate adjustment. The first IC chip 43 generates heat when performing signal processing. When the first IC chip 43 is at a high temperature (becomes hot), this leads to an increase in noise, a decrease in the quality of the video image, a slower processing speed, and accelerated component degradation. Therefore, a measure has been taken to cool the first IC chip 43. In addition, the image pickup apparatus 1 is equipped with a second IC chip 44. The second IC chip 44 is, for example, a power supply circuit and a field programmable gate array (an FPGA), and similar to the first IC chip 43, it is necessary to cool the second IC chip 44.

Most of the lens barrel 37 is covered by the case 70 (see FIG. 1A). A main circuit board 58 (a first circuit board) is disposed on a side face on the -Z side of the lens barrel 37. The first IC chip 43 and the second IC chip 44 are mounted on the main circuit board 58, and a heat dissipation rubber 45a and a heat dissipation rubber 45b (hereinafter, the heat dissipation rubber 45a or the heat dissipation rubber 45b is simply referred to as a heat dissipation rubber 45), which are heat conductive rubber, are attached (sticked) to these elements (the first IC chip 43 and the second IC chip 44), respectively. A face on the -Z side of the heat dissipation rubber 45 is in contact with a metal plate 46 that has high thermal conductivity, such as a copper plate or an aluminum plate. The main circuit board 58 is equipped with a controller such as a central processing unit (a CPU) that controls the image pickup device 36, the first IC chip 43, and the second IC chip 44.

One end portion of a graphite sheet 48 is attached to the metal plate 46, and the other end portion of the graphite sheet 48 is attached to the top (a face on the +Y side) of the other end portion of the graphite sheet 47 above the lens barrel 37. In other words, the other end portion of the graphite sheet 48 and the other end portion of the graphite sheet 47 are disposed to overlap with each other in a substantially vertical direction. The heat dissipation device 2 is fixed to the top (a face on the +Y side) of the other end portion of the graphite sheet 48 by using a double-sided tape 49 with high thermal conductivity.

Therefore, the heat dissipation device 2 is thermally connected to first heat generating elements (the first IC chip 43 and the second IC chip 44) by a first heat transfer member (the graphite sheet 48) which serves as a first heat transfer means. In addition, the heat dissipation device 2 is thermally connected to a second heat generating element (the image pickup device 36) by a second heat transfer member (the graphite sheet 47) which serves as a second heat transfer means.

With such a configuration, the heat generated by the image pickup device 36, which is a heat generating component (the second heat generating element), is transferred to the heat diffusion plate 34 (see FIGS. 3B and C) of the heat dissipation device 2 via the graphite sheet 47, the graphite sheet 48, and the double-sided tape 49. In addition, the heat generated by the first IC chip 43 and the second IC chip 44 is transferred to the heat diffusion plate 34 of the heat dissipation device 2 via the graphite sheet 48 and the double-sided tape 49.

The air intake ports 32 of the heat dissipation device 2 are in communication with the intake port 19 (see FIGS. 1A and 2A) of the case 70. In addition, the air exhaust port 33 of the heat dissipation device 2 is in communication with the exhaust port 28 (see FIG. 1B) of the case 70.

In FIG. 6B, a dashed arrow 60 indicates the flow of the air being drawn in and exhausted by the image pickup apparatus 1. The air drawn into the image pickup apparatus 1 through the intake port 19 is taken into the heat dissipation device 2 from the air intake ports 32, and then is discharged outside the image pickup apparatus 1 through the air exhaust port 33 and the exhaust port 28 along with the heat from the heat diffusion plate 34.

Here, the side face on the -Z side of the lens barrel 37 is defined as a first face, the back face (a face on the +X side) of the lens barrel 37 is defined as a second face, and the top face (a face on the +Y side) of the lens barrel 37 is defined as a third face. As shown in FIGS. 5A and 5B, the second face is substantially perpendicular to the first face. The third face is a face that is substantially perpendicular to the first face and the second face and is adjacent to the first face and the second face. Moreover, the third face is a face of the lens barrel 37 that is different from the face, on which the first grip portion 10 is located. The sensor circuit board 38 is disposed on the second face substantially parallel to the second face, and the main circuit board 58 is disposed on the first face substantially parallel to the first face. The heat dissipation device 2 is disposed on the third face so as to be substantially perpendicular to the sensor circuit board 38 and the main circuit board 58.

In other words, since the heat dissipation device 2 is located on the third face, rather than between the lens barrel 37 and the first grip portion 10 in the Z-axis direction, it is possible to reduce the distance between the lens barrel 37 and the first grip portion 10 in the Z-axis direction. As a result, the load on the user's hand when gripping the image pickup apparatus 1 is reduced, improving the grip capability.

In addition, the heat transfer effect of the heat transfer members such as the graphite sheet 47 and the graphite sheet 48 decreases as the heat transfer distance increases. However, since the heat dissipation device 2 is disposed at a position close to both the sensor circuit board 38 and the main circuit board 58, it is possible to efficiently cool the sensor circuit board 38 and the main circuit board 58.

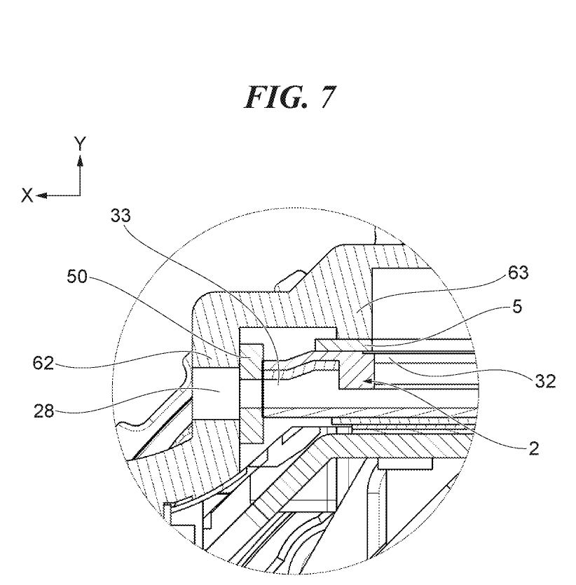

FIG. 7 is an enlarged view of an area E shown in FIG. 6B.

As shown in FIG. 5B, a soft elastic member 50 is disposed on the +Z side of the heat dissipation device 2, and a soft elastic member 51 is disposed on the +Y side of the heat dissipation device 2.

As shown in FIG. 7, the elastic member 50 is attached to an exterior portion 62 of the case 70 so as not to block the communicating portion between the exhaust port 28 of the case 70 and the air exhaust port 33. As a result, the elastic member 50 fills a gap between the area around the air exhaust port 33 and the exterior portion 62. In addition, the elastic member 51 is attached to the main face 2a of the heat dissipation device 2 so as not to block the communicating portion between the intake port 19 (see FIG. 6A) of the case 70 and the air intake ports 32. As a result, the elastic member 51 fills a gap between the area around the air intake ports 32 and an exterior portion 63 of the case 70.

The presence of the elastic member 50 and the elastic member 51 (due to the elastic member 50 and the elastic member 51 being provided) prevents water and dust from entering the image pickup apparatus 1. In addition, since the heat dissipation device 2 and the case 70 are connected via the elastic member 50 and the elastic member 51, the vibration from the heat dissipation device 2 is less likely to be transmitted to the user via the exterior portion 62 and the exterior portion 63. Furthermore, in the case where the image pickup apparatus 1 has fallen, the impact will not be directly transmitted to the heat dissipation device 2, thus suppressing the failure of the heat dissipation device 2.

As described above with reference to FIGS. 5A and 5B, by overlapping the graphite sheet 47, the graphite sheet 48, and the heat dissipation device 2 in the Y-axis direction, two heat dissipation paths are realized with the one heat dissipation device 2. In the present embodiment, in order to preferentially cool the heat of the first IC chip 43 and the main circuit board 58 over that of the image pickup device 36, starting from above (the +Y side), the heat dissipation device 2, the graphite sheet 48, and the graphite sheet 47 are arranged in order. However, depending on the priority of heat dissipation, the arrangement order of the graphite sheet 47 and the graphite sheet 48 in the Y-axis direction may be reversed.

The user may feel uncomfortable when a hot exhaust airflow (a high-temperature exhaust airflow) blows onto his/her body. Therefore, in the present embodiment, as shown in FIGS. 1B and 6B, the exhaust port 28 is disposed on a side face on the +Z side in a left-right direction (the Z-axis direction), so that the exhaust airflow flows above the display unit 6 in substantially the +Z direction. As a result, when gripping or operating the image pickup apparatus 1, the exhaust airflow is less likely to blow onto the user.

As shown in FIG. 6A, the accessory fixing portion 31 is located closer to the +X side than the microphone hole 30 and is located closer to the -X side than the intake port 19 and the exhaust port 28. Therefore, in the optical axis direction, the accessory fixing portion 31 is located between the microphone 29 (see FIG. 5A) and the heat dissipation device 2. Since the microphone hole 30 is not adjacent to the intake port 19 and the exhaust port 28, the microphone 29 (see FIG. 5A) becomes less likely to pick up the noise emitted by the heat dissipation device 2. Furthermore, since the intake port 19 and the exhaust port 28 do not face the microphone hole 30, it is effective in reducing noise.

An accessory (not shown) is attached to the accessory fixing portion 31, from the back in the -X direction. The heat dissipation device 2 is disposed closer to the -Y side than the accessory fixing portion 31. In other words, as shown in FIG. 6B, a maximum height of an exterior portion 65 of the case 70, which is a portion that covers the heat dissipation device 2, is lower than a maximum height of the accessory fixing portion 31. With this configuration, the heat dissipation device 2 is prevented from interfering with the attachment and detachment of the accessory (not shown).

As shown in FIG. 6B, a gap 64 is provided on the +Y side of the air intake ports 32 of the heat dissipation device 2 (is provided above the air intake ports 32 of the heat dissipation device 2), allowing the air to flow in the +Z direction, and the gap 64 is covered by the exterior portion 65 that has a roof shape. In other words, the gap 64 is formed between the heat dissipation device 2 and the case 70 (the exterior portion 65) above the air intake ports 32, and the exterior portion 65, the gap 64, and the air intake ports 32 are located in order from above. This configuration is capable of preventing rain from directly entering the heat dissipation device 2. It should be noted that in an image pickup apparatus where high splash resistance is not required, an intake port communicating directly above the air intake ports 32 may be provided.

According to the present embodiment, the main circuit board 58 is disposed on the side face on the -Z side of the lens barrel 37, the sensor circuit board 38 is disposed on the back face of the lens barrel 37, and the heat dissipation device 2 is disposed on the top face of the lens barrel 37. The top face of the lens barrel 37 is a face that is different from the face, on which the first grip portion 10 is located, and that is substantially perpendicular to the side face on the -Z side of the lens barrel 37 and the back face of the lens barrel 37 and is adjacent to the side face on the -Z side of the lens barrel 37 and the back face of the lens barrel 37. Therefore, since the heat dissipation device 2 is not located between the lens barrel 37 and the first grip portion 10, the grip capability is good. In addition, since the heat dissipation device 2 is thermally connected to the main circuit board 58 and the sensor circuit board 38 by the graphite sheet 48 and the graphite sheet 47, respectively, the cooling effect is high due to the two heat dissipation paths. Therefore, it is possible to improve the grip capability of the image pickup apparatus while suppressing a temperature rise inside the image pickup apparatus.

It should be noted that in the present embodiment, although the heat dissipation device 2 is disposed on the +Y side, the heat dissipation device 2 may be disposed on the -Y side (a bottom face of the lens barrel 37) relative to the lens barrel 37. Also in this case, since the distance between the sensor circuit board 38 and the heat dissipation device 2 and the distance between the main circuit board 58 and the heat dissipation device 2 are capable of being reduced, it is possible to obtain the same effects.

From this perspective, the respective arrangement faces of the main circuit board 58, the sensor circuit board 38, and the heat dissipation device 2, of the lens barrel 37 only need to be substantially perpendicular to one another and adjacent to one another, and are not limited to the example that has been described in the present embodiment.

It should be noted that in the present embodiment, the graphite sheet 47, the graphite sheet 48, the heat dissipation rubber 45, and the metal plate 46 have been used as the heat transfer members for thermally connecting the heat dissipation device 2 to the respective heat generating elements, but the heat transfer members of the present disclosure are not limited to these. For example, as the heat transfer member of the present disclosure, a gap filler, a heat conductive adhesive, a heat conductive grease, a heat pipe, or the like may be adopted.

In particular, in the case of using a heat pipe, by locating the heat dissipation device 2 above the image pickup device 36, the first IC chip 43, and the second IC chip 44 (by locating the heat dissipation device 2 closer to the +Y side than the image pickup device 36, the first IC chip 43, and the second IC chip 44), it is possible to achieve effective cooling. Specifically, this is because gravity can be used to help the liquid to be heated and evaporate, move upward, and then, after being cooled by the heat dissipation device 2, return to a liquid state and move downward.

Also in the case of adopting a heat transfer structure other than a heat pipe, the air heated by the image pickup device 36, the first IC chip 43, and the second IC chip 44 expands and its density decreases, causing it to rise. Therefore, the heat dissipation efficiency is increased by locating the heat dissipation device 2 above the lens barrel 37.

It should be noted that in the present embodiment, two L-shaped graphite sheets (the graphite sheet 47 and the graphite sheet 48) have been used as the heat transfer members, but the number of parts (components) may be reduced by integrating the two L-shaped graphite sheets (the graphite sheet 47 and the graphite sheet 48) into a single structure.

It should be noted that the image pickup apparatus, to which the present disclosure is applied, only needs to include a lens barrel and is not limited to a video camera.

According to the present disclosure, it is possible to improve the grip capability of the image pickup apparatus while suppressing the temperature rise inside the image pickup apparatus.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-079784, filed May 12, 2025, which is hereby incorporated by reference herein in its entirety.

What is claimed is:

1. An image pickup apparatus comprising:
a lens barrel;
a gripping portion for gripping a case of the image pickup apparatus;
a first circuit board, on which a first heat generating element is mounted, the first circuit board being disposed on a first face of the lens barrel;
a second circuit board, on which a second heat generating element is mounted, the second circuit board being disposed on a second face of the lens barrel that is substantially perpendicular to the first face; and
a heat dissipation device configured to be disposed on a third face of the lens barrel and have a flow path connecting an intake port provided in the case to an exhaust port provided in the case, and
wherein the third face is a face that is different from a face, on which the gripping portion is located, and that is substantially perpendicular to the first face and the second face and is adjacent to the first face and the second face, and
the heat dissipation device is thermally connected to the first heat generating element by a first heat transfer member, and is thermally connected to the second heat generating element by a second heat transfer member.

2. The image pickup apparatus according to claim 1, wherein
the first face is a side face, the second face is a back face, and the third face is a top face.

3. The image pickup apparatus according to claim 2, wherein
the heat dissipation device, the first heat transfer member, and the second heat transfer member are disposed to overlap with each other in a substantially vertical direction.

4. The image pickup apparatus according to claim 3, wherein
the second heat generating element is an image sensor, and
the heat dissipation device, the first heat transfer member, and the second heat transfer member are disposed in order from above.

5. The image pickup apparatus according to claim 2, wherein
the gripping portion is located on the first face of the lens barrel, and
the exhaust port provided in the case is disposed on a side opposite to the first face in a left-right direction.

6. The image pickup apparatus according to claim 1, wherein
the heat dissipation device includes a plurality of air intake ports disposed on a main face, and an air exhaust port opening in a direction substantially perpendicular to a back face and the main face.

7. The image pickup apparatus according to claim 6, wherein
the heat dissipation device draws in air from the air intake ports by a high-speed vibration of a thin film enclosed within the heat dissipation device, and discharges the drawn-in air from the air exhaust port.

8. The image pickup apparatus according to claim 6, wherein
a gap is formed between the heat dissipation device and the case above the air intake ports of the heat dissipation device, and
the case, the gap, and the air intake ports are located in order from above.

9. The image pickup apparatus according to claim 6, wherein
the air intake ports are in communication with the intake port, and the air exhaust port is in communication with the exhaust port.

10. The image pickup apparatus according to claim 2, further comprising:
a microphone; and
a mounting portion to which an external accessory is capable of being attached, and
wherein in an optical axis direction, the mounting portion is disposed between the microphone and the heat dissipation device.

11. The image pickup apparatus according to claim 2, further comprising:
a mounting portion to which an external accessory is capable of being attached, and
wherein a maximum height of a portion of the case, which covers the heat dissipation device, is lower than a maximum height of the mounting portion.

12. The image pickup apparatus according to claim 1, wherein
the heat dissipation device and the case are connected via an elastic member.

13. The image pickup apparatus according to claim 1, wherein
the first circuit board is equipped with a controller that controls the first heat generating element and the second heat generating element.
